(19) United States
(12) Patent Application Publication
(10) Pub. No.: US 2024/0377726 A1
(43) Pub. Date: Nov. 14, 2024

(54) PELLICLE, EXPOSURE ORIGINAL PLATE, EXPOSURE DEVICE AND PELLICLE PRODUCTION METHOD

(71) Applicant: MITSUI CHEMICALS, INC., Chuo-ku, Tokyo (JP)

(72) Inventors: Takashi UNEZAKI, Ichihara-shi, Chiba (JP); Kaichiro HARUTA, Ichihara-shi, Chiba (JP); Yasushi SATOH, Funabashi-shi, Chiba (JP); Ken ITO, Hiroshima-shi, Hiroshima (JP); Yosuke ONO, Sodegaura-shi, Chiba (JP); Masashi FUJIMURA, Ichihara-shi, Chiba (JP); Hisako ISHIKAWA, Ichihara-shi, Chiba (JP)

(73) Assignee: MITSUI CHEMICALS, INC., Chou-ku, Tokyo (JP)

(21) Appl. No.: 18/690,494

(22) PCT Filed: Sep. 12, 2022
(86) PCT No.: PCT/JP2022/034108

§ 371 Date: Mar. 8, 2024

(30) Foreign Application Priority Data
Sep. 13, 2021 (JP) 2021-148630

(51) Int. Cl. G03F 1/64; G03F 1/60

(52) U.S. Cl. CPC G03F 1/64; G03F 1/60

(57) ABSTRACT

The present disclosure provides a pellicle that includes: a pellicle frame; a pellicle film supported at one end surface of the pellicle frame; and an adhesive layer provided at another end surface of the pellicle frame, and satisfies the following Equation (1): [A_{60° C.}]≥4.0 gf/mm² (1). In Equation (1), [A_{60° C.}] represents a first peel strength when the pellicle is used in a test laminated body. The test laminated body is obtained by placing the pellicle on a quartz glass substrate such that the adhesive layer is in contact with a surface of the quartz glass substrate, and maintaining a load on the pellicle under prescribed conditions. The first peel strength represents a load per unit adhesion area, which load is required for peeling the pellicle included in the test laminated body from the quartz glass substrate using a standard universal tester under prescribed conditions.

### TECHNICAL FIELD

The present disclosure relates to a pellicle, an exposure original plate, an exposure device, and a pellicle production method.

### BACKGROUND ART

A technology for forming a pattern through application of a photosensitive substance to a surface of an object, such as an electronic component, a printed circuit board, or a display panel, and subsequent exposure of the applied substance in a pattern shape (i.e., photolithography) is known. In photolithography, a transparent substrate having a pattern formed on one side is used. This transparent substrate is called a photomask (hereinafter, also referred to as “original plate”). A pellicle is pasted to the photomask so as to inhibit the adhesion of foreign matters, such as dust, to the surface of the photomask.

In recent years, with enhancement in the resolution of exposure patterns, the use of extreme ultra violet (EUV) light having a shorter wavelength as an exposure light source has been expanded in place of using deep ultra violet (DUV) light.

Patent Document 1 discloses a pellicle in which post-peeling residues are reduced without an addition or the like of a compound such as a surface modifier. The pellicle disclosed in Patent Document 1 includes a pellicle frame, a pellicle film, and a pellicle adhesive. The pellicle film is stretched over an upper end surface of the pellicle frame. The pellicle adhesive is adhered to a lower end surface of the pellicle frame. The pellicle adhesive has a ratio of the peel strength and the tensile strength in a prescribed range.

Patent Document 2 discloses to control the amount of a polymerization initiator in an adhesive layer to be 8 ppm or less for the inhibition of haze, and describes that an alkyl (meth) acrylate containing an alkyl group having from 4 to 14 carbon atoms is preferred since it exhibits an appropriate strength of adhesion to a mask.

Patent Document 1: Japanese Patent Application Laid-Open (JP-A) No. 2018-21182

Patent Document 2: JP-A No. 2011-107469

### SUMMARY OF THE INVENTION

### Technical Problem

A photomask moves at a high speed during exposure. A pellicle needs to be maintained in an attached state so as to inhibit the adhesion of foreign matters to the photomask. Therefore, an adhesive layer of the pellicle is required to have such a peel strength that prevents the pellicle from being peeled off from the photomask during exposure.

EUV light is readily absorbed by the photomask. Thus, during exposure with EUV light, the temperature of the photomask is likely to be high. The heat of the photomask is conducted to the pellicle. The adhesive layer of the pellicle is likely to absorb scattered EUV light. Further, high-output and practical EUV light sources have been developed. Consequently, the pellicle is exposed to a high temperature during exposure with EUV light. Specifically, the temperature to which the pellicle is exposed is expected to be 60° C.

However, the peel strength of the pellicle disclosed in Patent Document 1 may be reduced when the pellicle is exposed to a high-temperature environment. As a result, the pellicle disclosed in Patent Document 1 may be peeled off from a photomask during EUV exposure.

Moreover, in conventional pellicles, in order to reduce a strain applied to a photomask from a pellicle at the time of attaching the pellicle to the photomask, a flexible adhesive layer is often used as an adhesive layer of the pellicle. However, the peel strength of such a flexible adhesive layer may be reduced by exposure to a high-temperature environment.

From these circumstances, a pellicle used for exposure with EUV light is demanded to be able to maintain a peel strength such that it is not peeled off from a photomask even in a high-temperature environment.

There is also a growing demand for a pellicle used for exposure with light other than EUV light, such as ArF, to have a high reliability for a further extension of working life.

The disclosure was made in view of the above-described circumstances.

An object of one embodiment of the disclosure is to provide: a pellicle that is unlikely to be peeled off from a photomask even when exposed to a high-temperature environment: an exposure original plate: an exposure device: and a pellicle production method.

The “high-temperature environment” refers to a temperature of 60° C.

### Solution to Problem

Means for solving the above-described problems encompass the following embodiments.
<1> A pellicle, including:
a pellicle frame:
a pellicle film supported at one end surface of the pellicle frame: and
an adhesive layer provided at another end surface of the pellicle frame,
wherein the pellicle satisfies the following Equation (1):

$$[ {A}_{6 {0}^{∘} C .} ] \geq 4. gf / {mm}^{2} \qquad Equation ( 1 )$$

wherein:
[A_{60° C.}] represents a first peel strength when the pellicle is used in a test laminated body,
the test laminated body is obtained by placing the pellicle on a quartz glass substrate such that the adhesive layer is in contact with a surface of the quartz glass substrate, maintaining a load of 5 kgf on the pellicle for 30 seconds, removing the load, and then leaving the resultant to stand at 23° C. for 24 hours, and
the first peel strength represents a load per unit adhesion area, which load is required for peeling the pellicle included in the test laminated body from the quartz glass substrate at a time of pulling the pellicle frame in a height direction of the pellicle frame at a rate of 0.1 mm/sec with respect to the quartz glass substrate using a standard universal tester under a condition that the temperature of the quartz glass substrate is 60°° C.
<2> The pellicle according to <1>, wherein the pellicle satisfies the following Equation (2):

$$( [ {A}_{6 {0}^{∘} C .} ] / [ {A}_{2 {3}^{∘} C .} ] ) > 0.35 \qquad Equation ( 2 )$$

wherein:
[A_{23° C.}] represents a second peel strength when the pellicle is used in the test laminated body, and
the second peel strength represents a load per unit adhesion area, which load is required for peeling the pellicle included in the test laminated body from the quartz glass substrate at a time of pulling the pellicle frame in the height direction of the pellicle frame at a rate of 0.1 mm/sec with respect to the quartz glass substrate using a standard universal tester under a condition that the temperature of the quartz glass substrate is 23° C.
<3> The pellicle according to <1> or <2>, wherein the pellicle satisfies the following Equation (3):

$$[ {A}_{2 {3}^{∘} C .} ] \leq 30. gf / {mm}^{2} \qquad Equation ( 3 )$$

<4> The pellicle according to any one of <1> to <3>, wherein the adhesive layer has a glass transition temperature Tg of higher than −25° C. and lower than 10° C.
<5> The pellicle according to any one of <1> to <4>, wherein the adhesive layer contains a copolymer of an alkyl (meth) acrylate monomer and a monomer having a functional group that is reactive with at least one of an isocyanate group, an epoxy group, or an acid anhydride.
<6> The pellicle according to <5>, wherein the alkyl (meth) acrylate monomer contains at least one of an alkyl group having from 1 to 3 carbon atoms or an alicyclic alkyl group.
<7> The pellicle according to <4>, wherein:
the adhesive layer contains a copolymer of an alkyl (meth) acrylate monomer and a monomer having a functional group that is reactive with at least one of an isocyanate group, an epoxy group, or an acid anhydride, and
the alkyl (meth) acrylate monomer contains at least one of an alkyl group having from 1 to 3 carbon atoms or an alicyclic alkyl group.
<8> The pellicle according to any one of <5> to <7>, wherein a content of the alkyl (meth) acrylate monomer is from 80 parts by mass to 99.5 parts by mass with respect to a total of 100 parts by mass of the monomers configuring the copolymer.
<9> The pellicle according to any one of <5> to <8>, wherein the content of the monomer having the functional group is from 0.5 parts by mass to 20 parts by mass with respect to a total of 100 parts by mass of the monomers configuring the copolymer.
<10> The pellicle according to any one of <5> to <9>, wherein:
the adhesive layer contains a reaction product of the copolymer and a crosslinking agent, and
the content of the crosslinking agent is from 0.002 parts by mass to 3.000 parts by mass with respect to a total of 100 parts by mass of the monomers configuring the copolymer.
<11> An exposure original plate, including:
an original plate having a pattern; and
the pellicle according to any one of <1> to <10>, which is attached to a surface of the original plate at a side having the pattern.
<12> An exposure device, including:
a light source that emits an exposure light:
the exposure original plate according to <11>; and
an optical system that guides the exposure light emitted from the light source to the exposure original plate,
wherein the exposure original plate is arranged such that the exposure light emitted from the light source transmits through the pellicle film and is irradiated onto the original plate.
<13> A method of producing the pellicle according to any one of <1> to <10>, the method including:
a step of attaching the pellicle film to one end surface of the pellicle frame; and
a step of forming the adhesive layer by applying a coating composition to the other end surface of the pellicle frame and heating the applied coating composition,
wherein the coating composition contains a copolymer of an alkyl (meth) acrylate monomer and a monomer having a functional group that is reactive with at least one of an isocyanate group, an epoxy group, or an acid anhydride.

### Advantageous Effects of Invention

According to the disclosure, a pellicle that is unlikely to be peeled off from an original plate even when exposed to a high-temperature environment, an exposure original plate, an exposure device, and a pellicle production method are provided.

### BRIEF DESCRIPTION OF DRAWING

FIG. 1 is a schematic cross-sectional view illustrating a cross-section of a pellicle according to one Example.

### DESCRIPTION OF EMBODIMENTS

In the disclosure, those numerical ranges that are expressed with “to” each means a range that includes the numerical values stated before and after “to” as the minimum value and the maximum value, respectively.

In a set of numerical ranges that are stated in a stepwise manner in the disclosure, the upper limit value or the lower limit value of one numerical range may be replaced with the upper limit value or the lower limit value of other numerical range, or may be replaced with a relevant value indicated in any of Examples.

In the disclosure, a combination of two or more preferred aspects is a more preferred aspect.

In the disclosure, when there are plural kinds of substances that correspond to a component, an indicated amount of the component means, unless otherwise specified, a total amount of the plural kinds of substances.

In the disclosure, the term “step” encompasses not only a discrete step but also a step that cannot be clearly distinguished from other steps, as long as the intended purpose of the step is achieved.

In the disclosure, the expression “(meth) acryl” means one or both of “acryl” and “methacryl”.

### (1) EMBODIMENTS

### (1.1) Pellicle

The pellicle according to one embodiment of the disclosure includes a pellicle frame, a pellicle film, and an adhesive layer. The pellicle film is supported at one end surface of the pellicle frame. The adhesive layer is provided at another end surface of the pellicle frame. The pellicle according to one embodiment satisfies the following Equation (1).

$$[ {A}_{6 {0}^{∘} C .} ] \geq 4. gf / {mm}^{2} \qquad Equation ( 1 )$$

In Equation (1), [A_{60° C.}] represents a first peel strength when the pellicle is used in a test laminated body.

The test laminated body is obtained by placing the pellicle on a quartz glass substrate such that the adhesive layer is in contact with a surface of the quartz glass substrate, maintaining a load of 5 kgf on the pellicle for 30 seconds, removing the load, and then leaving the resultant to stand at 23° C. for 24 hours.

The first peel strength represents a load per unit adhesion area, which load is required for peeling the pellicle included in the test laminated body from the quartz glass substrate at a time of pulling the pellicle frame in a height direction of the pellicle frame at a rate of 0.1 mm/sec with respect to the quartz glass substrate using a standard universal tester under a condition that the temperature of the quartz glass substrate is 60° C.

The details of a method of measuring the first peel strength will be described below in the section of Examples.

In the disclosure, the reason why the temperature of the quartz glass substrate at the time of measuring the first peel strength is set at 60° C. is because the temperature to which the pellicle is exposed is expected to be 60° C. during exposure with EUV light.

The pellicle according to one embodiment has the above-described constitution, and is thus unlikely to be peeled off from an original plate even when exposed to a high-temperature environment (e.g., 60°° C.). The original plate will be described below.

DUV light is hardly absorbed by an original plate or the like. Therefore, during exposure with DUV light, the temperature to which the pellicle is exposed is expected to be room temperature (23° C.) or so. However, even in the case of using the pellicle according to one embodiment for exposure with DUV light, there is a need for improvement of the first peel strength in a high-temperature environment. The pellicle according to one embodiment can meet such a need. In other words, the pellicle according to one embodiment has excellent reliability.

### (1.1.1) First Peel Strength

The pellicle according to one embodiment satisfies Equation (1).

A lower limit of [A_{60° C.}] is 4.0 gf/mm² or more, preferably 5.0 gf/mm² or more, more preferably 8.0 gf/mm² or more, still more preferably 10.0 gf/mm² or more.

When the lower limit of [A_{60° C.}] is 5.0 gf/mm² or more, the pellicle can be made less likely to be peeled off from an original plate even when the pellicle is exposed to a high-temperature environment, so that superior reliability can be expected.

An upper limit of [A_{60° C.}] is not limited and may be, for example, 30.0 gf/mm² or less, 25.0 gf/mm² or less, or 20.0 gf/mm² or less.

From these standpoints, [A_{60° C.}] is preferably from 4.0 gf/mm² to 30.0 gf/mm², more preferably from 5.0 gf/mm² to 30.0 gf/mm², still more preferably from 8.0 gf/mm² to 30.0 gf/mm², particularly preferably from 10.0 gf/mm² to 30.0 gf/mm². [A_{60° C.}] is also preferably from 8.0 gf/mm² to 25.0 gf/mm², more preferably from 8.0 gf/mm² to 20.0 gf/mm².

[A_{60° C.}] is the lowest in the absence of exposure history, and tends to be increased as the number of exposures increases.

[A_{60° C.}] is preferably evaluated in the absence of exposure history; however, it may be evaluated after an exposure.

### (1.1.2) Peel Strength Ratio

The pellicle according to one embodiment preferably satisfies the following Equation (2).

$$( [ {A}_{6 {0}^{∘} C .} ] / [ {A}_{2 {3}^{∘} C .} ] ) > 0.35 \qquad Equation ( 2 )$$

In Equation (2), [A_{23° C.}] represents a second peel strength when the pellicle is used in the test laminated body.

The second peel strength represents a load per unit adhesion area, which load is required for peeling the pellicle included in the test laminated body from the quartz glass substrate at a time of pulling the pellicle frame in the height direction of the pellicle frame at a rate of 0.1 mm/sec with respect to the quartz glass substrate using a standard universal tester under a condition that the temperature of the quartz glass substrate is 23° C.

The details of a method of measuring the second peel strength will be described below in the section of Examples.

In the disclosure, the reason why the temperature of the quartz glass substrate at the time of measuring the second peel strength is set at 23° C. is because the temperature at which the pellicle is peeled off from an original plate for replacement of the pellicle pasted to the original plate is 23° C.

When the pellicle according to one embodiment satisfies Equation (2), the generation of adhesive residue can be inhibited. Particularly, with the pellicle satisfying Equation (1) at the same time, not only the pellicle can be made unlikely to be peeled off from an original plate even when exposed to a high-temperature environment (e.g., 60° C.), but also the generation of adhesive residue can be inhibited.

The term “adhesive residue” used herein refers to that at least a portion of the adhesive layer remains on an original plate after peeling the pellicle from the original plate.

In order to improve the first peel strength simply, it is considered to employ a method of increasing the glass transition temperature of an adhesive. However, with a mere increase in the glass transition temperature, a high second peel strength is required at the time of peeling the pellicle from an original plate, making the generation of adhesive residue likely to occur. By allowing the pellicle to satisfy Equation (2), not only the pellicle is made unlikely to be peeled off from the original plate even when exposed to a high-temperature environment, but also the generation of adhesive residue can be inhibited.

A lower limit of ([A_{60° C.}]/[A_{23° C.}]) is preferably 0.40 or more, more preferably 0.45 or more, still more preferably 0.48 or more, particularly preferably 0.50 or more.

When the lower limit of ([A_{60° C.}]/[A_{23° C.}]) is 0.35 or more, the amount of adhesive residue at normal temperature can be reduced while making the pellicle unlikely to be peeled off from an original plate in a high-temperature environment (e.g., 60° C.). An upper limit of ([A_{60° C.}]/[A_{23° C.}]) is not limited and may be, for example, 2.00 or less, and it is preferably 1.00 or less, more preferably 0.80 or less, still more preferably 0.70 or less.

From these standpoints, the value of ([A_{60° C.}]/[A_{23° C.}]) is preferably from 0.40 to 2.00, more preferably from 0.45 to 2.00, still more preferably from 0.48 to 2.00, particularly preferably from 0.50 to 2.00. The value of ([A_{60° C.}]/[A_{23° C.}]) is also preferably from 0.45 to 1.00, more preferably from 0.45 to 0.80, still more preferably from 0.45 to 0.70.

[A_{23° C.}] is the lowest in the absence of exposure history, and tends to be increased as the number of exposures increases.

[A_{23° C.}] is preferably evaluated in the absence of exposure history: however, it may be evaluated after an exposure.

As a method for satisfying Equation (2), for example, a method of adjusting a content of the below-described crosslinking agent may be employed. Specific examples thereof include a method of adjusting the content of the crosslinking agent to be from 0.002 parts by mass to 3.000 parts by mass with respect to a total of 100 parts by mass of monomers configuring the below-described copolymer.

### (1.1.3) Second Peel Strength

A lower limit of [A_{23° C.}] is not limited; however, in order to inhibit the occurrence of peeling of the pellicle from an original plate, the lower limit of [A_{23° C.}] is preferably 4.0 gf/mm² or more, more preferably 6.0 gf/mm² or more, still more preferably 10.0 gf/mm² or more, particularly preferably 15.0 gf/mm² or more.

An upper limit of [A_{23° C.}] is not limited: however, in order to inhibit the occurrence of damage to an original plate and the generation of adhesive residue at a time of peeling the pellicle from the original plate, the upper limit of [A_{23° C.}] is preferably 40.0 gf/mm² or less, more preferably 30.0 gf/mm² or less, still more preferably 26.0 gf/mm² or less, particularly preferably 20.0 gf/mm² or less.

From these standpoints, [A_{23° C.}] is preferably from 4.0 gf/mm² to 40.0 gf/mm², more preferably from 4.0 gf/mm² to 30.0 gf/mm², still more preferably from 4.0 gf/mm² to 26.0 gf/mm², particularly preferably from 4.0 gf/mm² to 20.0 gf/mm². [A_{23° C.}] is also preferably from 6.0 gf/mm² to 26.0 gf/mm², more preferably from 10.0 gf/mm² to 26.0 gf/mm², still more preferably from 15.0 gf/mm² to 26.0 gf/mm².

### (1.1.4) Adhesive Layer

The pellicle according to one embodiment includes an adhesive layer.

The adhesive layer enables to adhere the pellicle according to one embodiment to an original plate.

The adhesive layer is a gel-like viscoelastic body. The adhesive layer exhibits a viscosity and a cohesive strength. The term “viscosity” used herein refers to such a property of a liquid that gradually wets an original plate, which is an adherend, upon coming into contact therewith. The term “cohesive strength” used herein refers to such a property of a solid that exhibits a resistance to peeling from an original plate.

As described below; the adhesive layer is formed by processing a coating composition through application, heating, drying, curing, and the like.

### (1.1.4.1) Glass Transition Temperature

The adhesive layer preferably has a glass transition temperature Tg of higher than −25° C. and lower than 10° C. By this, the adhesive layer exhibits an adhesive strength in a use temperature range (e.g., 20° C. or higher) of the pellicle, making the pellicle less likely to be peeled off from an original plate even when exposed to a high-temperature environment. From the standpoint of making the pellicle less likely to be peeled off from an original plate even when exposed to a high-temperature environment, a lower limit of the glass transition temperature Tg of the adhesive layer is preferably higher than −25° C., more preferably −22°° C. or higher, still more preferably −20° C. or higher, most preferably −18° C. or higher.

From the standpoint of imparting adhesiveness at normal temperature, an upper limit of the glass transition temperature Tg of the adhesive layer is preferably lower than 10° C., more preferably 5°° C. or lower, still more preferably 0° C. or lower.

From the standpoint of facilitating the reduction of strain of an original plate caused by distortion of the pellicle frame, the upper limit of the glass transition temperature Tg of the adhesive layer is preferably −5° C. or lower, more preferably −10° C. or lower.

From these standpoints, the glass transition temperature Tg is preferably higher than −25° C. but 5° C. or lower, more preferably higher than −25° C. but 0° C. or lower, still more preferably higher than −25° C. but −5° C. or lower, yet still more preferably higher than −25° C. but −10° C. or lower, yet still more preferably from −22°° C. to −10° C., particularly preferably from −20°° C. to −10° C., further preferably from −18° C. to −10° C.

The glass transition temperature Tg of the adhesive layer is measured by the same method as described below in the section of Examples.

### (1.1.4.2) Coating Composition

The coating composition contains a compound selected from various polymers, solvents, crosslinking agents, catalysts, initiators, and the like in accordance with the adhesive layer to be formed. The coating composition is a precursor of an adhesive composition. In other words, an adhesive composition is obtained by curing the coating composition.

### (1.1.4.3) Adhesive Composition

Examples of the adhesive composition include, but not particularly limited to, acrylic, silicone-based, styrene butadiene-based, urethane-based, and olefin-based adhesives. Thereamong, from the standpoint of, for example, reducing the amount of outgas generated from the pellicle, the adhesive composition is preferably an acrylic adhesive.

The acrylic adhesive will now be described.

### (1.1.4.4) Acrylic Adhesive

The acrylic adhesive preferably contains an alkyl (meth)acrylate copolymer.

### (1.1.4.4.1) Alkyl (meth)acrylate Copolymer

The alkyl (meth) acrylate copolymer preferably contains a copolymer of:
an alkyl (meth) acrylate monomer: and
a monomer having a functional group that is reactive with at least one of an isocyanate group, an epoxy group, or an acid anhydride (this monomer is hereinafter also referred to as “functional group-containing monomer”).

The copolymer of an alkyl (meth)acrylate monomer and a functional group-containing monomer is hereinafter also referred to as “the copolymer”.

The acrylic adhesive contains the alkyl (meth)acrylate copolymer: therefore, the pellicle has a sufficient first peel strength, and the generation of adhesive residue can be inhibited.

The alkyl (meth) acrylate copolymer has a weight-average molecular weight (Mw) of preferably from 30,000 to 2,500,000, more preferably from 50,000 to 1,500,000, still more preferably from 70,000 to 1,200,000.

When an upper limit of the weight-average molecular weight (Mw) of the alkyl (meth) acrylate copolymer is 2,500,000 or less, the solution viscosity can be controlled in range where the coating composition can be easily processed even with an increase in the solid concentration of the coating composition. The upper limit of the weight-average molecular weight (Mw) of the alkyl (meth) acrylate copolymer is preferably 2,500,000 or less, more preferably 1,500,000 or less, still more preferably 1,200,000 or less.

When a lower limit of the weight-average molecular weight (Mw) of the alkyl (meth) acrylate copolymer is 30,000 or more, the pellicle has an appropriate first peel strength, and the generation of adhesive residue can be inhibited. The lower limit of the weight-average molecular weight (Mw) of the alkyl (meth) acrylate copolymer is preferably 30,000 or more, more preferably 50,000 or more, still more preferably 70,000 or more.

The weight-average molecular weight (Mw) of the alkyl (meth) acrylate copolymer is measured by gel permeation chromatography (GPC), and the details of a measurement method will be described below in the section of Examples.

For example, generally, a higher monomer concentration during a polymerization reaction tends to lead to a larger weight-average molecular weight (Mw), and a smaller amount of a polymerization initiator and a lower polymerization temperature tend to lead to a larger weight-average molecular weight (Mw). The weight-average molecular weight can be controlled by adjusting the monomer concentration, the amount of the polymerization initiator, and the polymerization temperature.

The alkyl (meth) acrylate copolymer has a number-average molecular weight (Mn) of preferably from 5,000 to 500,000, more preferably from 8,000 to 300,000, still more preferably from 10,000 to 200,000, most preferably from 20,000 to 200,000.

When an upper limit of the number-average molecular weight (Mn) of the alkyl (meth)acrylate copolymer is 500,000 or less, the solution viscosity can be controlled in range where the coating composition can be easily processed even with an increase in the solid concentration of the coating composition. The upper limit of the number-average molecular weight (Mn) of the alkyl (meth)acrylate copolymer is preferably 500,000 or less, more preferably 300,000 or less, still more preferably 200,000 or less.

When a lower limit of the number-average molecular weight (Mn) of the alkyl (meth)acrylate copolymer is 5,000 or more, the pellicle has an appropriate first peel strength, and the generation of adhesive residue can be inhibited. The lower limit of the number-average molecular weight (Mn) of the alkyl (meth) acrylate copolymer is preferably 5,000 or more, more preferably 8,000 or more, still more preferably 10,000 or more, most preferably 20,000 or more.

The number-average molecular weight (Mn) of the alkyl (meth)acrylate copolymer is measured by gel permeation chromatography (GPC), and the details of a measurement method will be described below in the section of Examples.

The alkyl (meth)acrylate copolymer has a ratio “weight-average molecular weight (Mw)/number-average molecular weight (Mn)” (hereinafter, also denoted as “Mw/Mn”) of preferably from 1.0 to 10.0, more preferably from 2.0 to 9.0, still more preferably from 2.5 to 8.0, most preferably from 3.0 to 7.0.

When the ratio Mw/Mn is in this range, the alkyl (meth)acrylate copolymer can be easily produced, and the amount of adhesive residue can be reduced.

When an upper limit of the ratio Mw/Mn is 10.0 or lower, the generation of adhesive residue can be inhibited. The upper limit of the ratio Mw/Mn is preferably 10.0 or lower, more preferably 9.0 or lower, still more preferably 8.0 or lower, most preferably 7.0 or lower.

When a lower limit of the ratio Mw/Mn is 1.0 or higher, the alkyl (meth)acrylate copolymer can be easily produced. The lower limit of the ratio Mw/Mn is preferably 1.0 or higher, more preferably 2.0 or higher, still more preferably 2.5 or higher, most preferably 3.0 or higher.

The alkyl (meth)acrylate monomer preferably contains an alkyl (meth)acrylate monomer containing an alkyl group having from 1 to 14 carbon atoms. The alkyl (meth)acrylate monomer containing an alkyl group having from 1 to 14 carbon atoms is, for example, a (meth)acrylate monomer of a linear aliphatic alcohol, a (meth)acrylate monomer of a branched aliphatic alcohol, or a (meth)acrylate monomer of a cyclic aliphatic alcohol.

Examples of the (meth)acrylate monomer of a linear aliphatic alcohol include methyl (meth)acrylate, ethyl (meth)acrylate, butyl (meth)acrylate, propyl (meth)acrylate, hexyl (meth)acrylate, octyl (meth)acrylate, decyl (meth)acrylate, dodecyl (meth)acrylate, and lauryl (meth)acrylate.

Examples of the (meth)acrylate monomer of a branched aliphatic alcohol include isobutyl (meth)acrylate, isoamyl (meth)acrylate, 2-ethylhexyl (meth)acrylate, isooctyl (meth)acrylate, and isononyl (meth)acrylate. These may be used singly, or in combination of two or more kinds thereof.

Examples of the (meth)acrylate monomer of a cyclic aliphatic alcohol include cyclohexyl (meth)acrylate and dicyclopentenyloxyethyl (meth)acrylate.

Thereamong, the alkyl (meth)acrylate monomer is preferably one which contains at least one of an alkyl group having from 1 to 3 carbon atoms or an alicyclic alkyl group.

An alkyl (meth)acrylate monomer which contains at least one of an alkyl group having from 1 to 3 carbon atoms or an alicyclic alkyl group is hereinafter referred to as “high-Tg monomer”. It is noted here that “Tg” denotes glass transition temperature.

In order to further reduce the amount of generated outgas, the alkyl (meth)acrylate monomer is more preferably an alkyl acrylate monomer that contains an alkyl group having from 1 to 3 carbon atoms or an alicyclic alkyl group, still more preferably an alkyl acrylate monomer that contains an alkyl group having from 1 to 3 carbon atoms. When the alkyl (meth)acrylate monomer is an alkyl acrylate monomer containing an alicyclic alkyl group, from the standpoint of availability, the number of carbons of the alicyclic alkyl group is preferably from 5 to 10.

By incorporating a high-Tg monomer into the alkyl (meth)acrylate monomer, a high first peel strength can be maintained even in a high-temperature atmosphere.

Specific examples of the high-Tg monomer include methyl acrylate, ethyl acrylate, propyl acrylate, isopropyl acrylate, cyclohexyl acrylate, dicyclopentanyl acrylate, methyl methacrylate, ethyl methacrylate, propyl methacrylate, isopropyl methacrylate, cyclohexyl methacrylate, and dicyclopentanyl methacrylate.

Thereamong, in order to make a high first peel strength more likely to be maintained even in a high-temperature atmosphere, the alkyl (meth)acrylate monomer preferably contains at least one of an alkyl group having from 1 to 2 carbon atoms or an alicyclic alkyl group, more preferably contains an alkyl group having from 1 to 2 carbon atoms.

It is preferred that:
the alkyl (meth)acrylate copolymer contains a copolymer of an alkyl (meth)acrylate monomer and a monomer having a functional group that is reactive with at least one of an isocyanate group, an epoxy group, or an acid anhydride; and
the alkyl (meth)acrylate monomer contains at least one of an alkyl group having from 1 to 3 carbon atoms or an alicyclic alkyl group.

By this, not only the pellicle has a sufficient first peel strength and can inhibit the generation of adhesive residue, but also the amount of generated outgas can be further reduced.

A content of the alkyl (meth)acrylate monomer is preferably from 80 parts by mass to 99.5 parts by mass, more preferably from 85 parts by mass to 99.5 parts by mass, still more preferably from 87 parts by mass to 99.5 parts by mass, with respect to a total of 100 parts by mass of the monomers configuring the copolymer.

When the content of the alkyl (meth)acrylate monomer is in a range of from 80 parts by mass to 99.5 parts by mass, an appropriate adhesive strength can be realized.

From the standpoint of realizing an appropriate adhesive strength and making a high first peel strength more likely to be maintained even in a high-temperature atmosphere, the content of the alkyl (meth)acrylate monomer, which is at least one of an alkyl group having from 1 to 3 carbon atoms or an alicyclic alkyl group, is preferably in a range of from 80 parts by mass to 99.5 parts by mass. From the same standpoint, the content of the alkyl (meth)acrylate monomer, which is at least one of an alkyl group having from 1 to 2 carbon atoms or an alicyclic alkyl group, is more preferably in a range of from 80 parts by mass to 99.5 parts by mass. From the same standpoint, the content of the alkyl (meth)acrylate monomer which is an alkyl group having from 1 to 2 carbon atoms is more preferably in a range of from 80 parts by mass to 99.5 parts by mass.

The functional group-containing monomer is a monomer copolymerizable with the alkyl (meth)acrylate monomer. The functional group-containing monomer contains a functional group that is reactive with at least one of an isocyanate group, an epoxy group, or an acid anhydride.

The functional group-containing monomer is, for example, a carboxy group-containing monomer, a hydroxy group-containing monomer, or an epoxy group-containing monomer.

Examples of the carboxy group-containing monomer include (meth)acrylic acid, itaconic acid, (meth)acrylic acid-itaconic acid, maleic acid, and crotonic acid.

Examples of the hydroxy group-containing monomer include 2-hydroxyethyl (meth)acrylate, 3-hydroxypropyl (meth)acrylate, 2-hydroxypropyl (meth)acrylate, and 4-hydroxy butyl (meth) acrylate.

Examples of the epoxy group-containing monomer include glycidyl (meth)acrylate. These monomers may be used singly, or in combination of two or more kinds thereof.

Particularly, from the standpoint of copolymerizability, general versatility, and the like, the functional group-containing monomer preferably contains a hydroxy group-containing (meth)acrylic acid containing a hydroxy alkyl group having from 2 to 4 carbon atoms, or glycidyl (meth)acrylate that is an epoxy group-containing monomer. Examples of the hydroxy group-containing (meth)acrylic acid containing a hydroxyalkyl group having from 2 to 4 carbon atoms include 2-hydroxyethyl (meth)acrylate, 2-hydroxypropyl (meth)acrylate, 2-hydroxy butyl (meth)acrylate, and 4-hydroxy butyl (meth)acrylate.

A content of the functional group-containing monomer is preferably, for example, from 0.5 parts by mass to 20 parts by mass with respect to a total of 100 parts by mass of the monomers configuring the copolymer.

From the standpoint of improving the adhesive strength of the adhesive layer, a lower limit of the content of the functional group-containing monomer is more preferably 1 part by mass or more, still more preferably 2 parts by mass or more, particularly preferably 3 parts by mass or more, with respect to a total of 100 parts by mass of the monomers configuring the alkyl (meth) acrylate copolymer.

From the standpoint of allowing the adhesive layer to have an appropriate adhesive strength, an upper limit of the content of the functional group-containing monomer is more preferably 15 parts by mass or less, still more preferably 10 parts by mass or less, with respect to a total of 100 parts by mass of the monomers configuring the alkyl (meth)acrylate copolymer.

### (1.1.4.4.2) Polymerization Method

A method of polymerizing the alkyl (meth)acrylate copolymer is not particularly limited, and examples thereof include solution polymerization, bulk polymerization, emulsion polymerization, and various radical polymerization methods.

The alkyl (meth)acrylate copolymer obtained by any of these polymerization methods may be any of a random copolymer, a block copolymer, a graft copolymer, and the like.

### (1.1.4.4.3) Polymerization Solvent

A reaction solution contains a polymerization solvent.

In solution polymerization, for example, propyl acetate, ethyl acetate, or toluene can be used as the polymerization solvent. By this, the viscosity of the resulting copolymer solution can be adjusted. This consequently makes it easy to control the thickness and the width of the coating composition at the time of the polymerization. Examples of a dilution solvent include propyl acetate, acetone, ethyl acetate, and toluene.

The viscosity of the copolymer solution is preferably 1,000 Pa·s or less, more preferably 500 Pa·s or less, still more preferably 200 Pa·s or less.

The viscosity of the coating composition is the viscosity determined when the temperature of the coating composition is 25° C., and can be measured using an E-type viscometer.

### (1.1.4.4.4) Solution Polymerization

One example of solution polymerization is a method of adding a polymerization initiator to a mixed solution of monomers in a stream of inert gas such as nitrogen to perform a polymerization reaction at temperature of from 50° C. to 100°° C. for a period of from 4 hours to 30 hours.

The polymerization initiator is, for example, an azo-based polymerization initiator or a peroxide-based polymerization initiator. Examples of the azo-based polymerization initiator include 2,2′-azobisisobutyronitrile (AIBN), 2,2′-azobis-2-methylbutyronitrile, dimethyl-2,2′-azobis (2-methylpropionate), and 4,4′-azobis-4-cyanovaleric acid. Examples of the peroxide-based polymerization initiator include benzoyl peroxide.

A content of the polymerization initiator is preferably from 0.01 parts by mass to 2.0 parts by mass with respect to a total of 100 parts by mass of all monomers configuring the alkyl (meth) acrylate copolymer.

In solution polymerization, in addition to the polymerization initiator, a chain transfer agent, an emulsifying agent, and the like may be added to the mixed solution of monomers. As the chain transfer agent, the emulsifying agent, and the like, any known agents can be selected and used as appropriate.

The amount of the polymerization initiator remaining in the adhesive layer is preferably small. By this, the amount of outgas generated during exposure can be reduced.

Examples of a method of reducing the amount of the polymerization initiator remaining in the adhesive layer include: a method of minimizing the amount of the polymerization initiator added at the time of polymerizing the alkyl (meth)acrylate copolymer: a method of using a polymerization initiator that is readily thermally decomposed: and a method including the steps of applying and drying an adhesive, in which the adhesive is heated to a high temperature for an extended period and the polymerization initiator is decomposed in the drying step.

A 10-hour half-life temperature is used as an index that represents the thermal decomposition rate of the polymerization initiator. A “half-life” represents the time required for one half of the polymerization initiator to be decomposed. A “10-hour half-life temperature” represents the temperature at which the half-life is 10 hours.

As the polymerization initiator, it is preferred to use a polymerization initiator having a low: 10-hour half-life temperature. The lower the 10-hour half-life temperature, the more easily is the polymerization initiator thermally decomposed. As a result, the polymerization initiator is less likely to remain in the adhesive layer.

The 10-hour half-life temperature of the polymerization initiator is preferably 80° C. or lower, more preferably 75° C. or lower.

Examples of an azo-based polymerization initiator having a low 10-hour half-life temperature include 2,2′-azobis (4-methoxy-2,4-dimethylvaleronitrile) (10-hour half-life temperature: 30° C.), 2,2′-azobisisobutyronitrile (10-hour half-life temperature: 65° C.), 2,2-azobis (2,4-dimethylvaleronitrile) (10-hour half-life temperature: 51° C.), dimethyl-2,2′-azobis (2-methylpropionate) (10-hour half-life temperature: 66°° C.), and 2,2′-azobis (2-methylbutyronitrile) (10-hour half-life temperature: 67° C.).

Examples of a peroxide-based polymerization initiator having a low 10-hour half-life temperature include dibenzoyl peroxide (10-hour half-life temperature: 74° C.) and dilauroyl peroxide (10-hour half-life temperature: 62° C.).

### (1.1.4.4.5) Crosslinking Agent

A crosslinking agent is a compound that contributes to the formation of a three-dimensional network structure through a reaction of a functional group of the compound with the copolymer. The acrylic adhesive preferably contains a reaction product of the alkyl (meth)acrylate copolymer and such a crosslinking agent. By this, the cohesive strength of the resulting adhesive layer is improved, so that the generation of adhesive residue can be inhibited, and the adhesive strength at a high temperature can be enhanced.

The crosslinking agent has at least one of an isocyanate group, an epoxy group, an acid anhydride, or a radical generating group.

Examples of the crosslinking agent include monofunctional epoxy compounds, polyfunctional epoxy compounds, acid anhydride compounds, metal salts, metal alkoxides, aldehyde compounds, non-amino resin-based amino compounds, urea compounds, isocyanate compounds, metal chelate compounds, melamine compounds, aziridine compounds, azo-based radical generators, and organic peroxides.

Thereamong, in terms of having excellent reactivity with a functional group component of the alkyl (meth) acrylate copolymer, the crosslinking agent is more preferably at least one of a monofunctional epoxy compound, a polyfunctional epoxy compound, an isocyanate compound, or an acid anhydride compound, still more preferably an acid anhydride compound.

Examples of the monofunctional epoxy compound include glycidyl (meth)acrylate, glycidyl acetate, butyl glycidyl ether, and phenyl glycidyl ether.

Examples of the polyfunctional epoxy compound include neopentyl glycol diglycidyl ether, polyethylene glycol diglycidyl ether, bisphenol A diglycidyl ether, bisphenol F diglycidyl ether, diglycidyl phthalate, dimer acid diglycidyl ester, triglycidyl isocyanurate, diglycerol triglycidyl ether, sorbitol tetraglycidyl ether, N,N,N′,N′-tetraglycidyl-m-xylenediamine, 1,3-bis (N,N-diglycidylaminomethyl) cyclohexane, and N,N,N′,N′-tetraglycidyldiaminodiphenylmethane.

Examples of the acid anhydride compound include aliphatic dicarboxylic acid anhydrides and aromatic polycarboxylic acid anhydrides.

Examples of the aliphatic dicarboxylic acid anhydrides include maleic anhydride, hexahydrophthalic anhydride, hexahydro-4-methyl phthalic anhydride, bicyclo [2.2.1] heptan-2,3-dicarboxylic anhydride, 2-methylbicyclo [2.2.1] heptan-2,3-dicarboxylic anhydride, and tetrahydrophthalic anhydride.

Examples of the aromatic polycarboxylic acid anhydrides include phthalic anhydride and trimellitic anhydride.

Examples of the isocyanate compound include xylylene diisocyanate, hexamethylene diisocyanate, and tolylene diisocyanate, as well as multimers, derivatives, and polymers thereof. These compounds may be used singly, or in combination of two or more kinds thereof.

The crosslinking agent may be a product. Examples of a crosslinking agent product include “RIKACID MH-700G” manufactured by New Japan Chemical Co., Ltd.

The above-described adhesive layer contains a reaction product of the copolymer and the crosslinking agent, and the content of the crosslinking agent is preferably from 0.002 parts by mass to 3.000 parts by mass with respect to a total of 100 parts by mass of the monomers configuring the copolymer.

The content of the crosslinking agent is preferably from 0.002 parts by mass to 3.000 parts by mass with respect to a total of 100 parts by mass of the monomers configuring the copolymer and, from the standpoint of, for example, obtaining an adhesive layer in which an adhesive residue is hardly generated and a stress on the flatness of an original plate is mitigated, the content of the crosslinking agent is more preferably from 0.002 parts by mass to 2.000 parts by mass, still more preferably from 0.005 parts by mass to 2.000 parts by mass, yet still more preferably from 0.01 parts by mass to 1.000 parts by mass, particularly preferably from 0.1 parts by mass to 0.500 parts by mass.

When an upper limit of the content of the crosslinking agent is 3.000 parts by mass or less, the crosslinking density of the alkyl (meth)acrylate copolymer is prevented from being excessively high. Therefore, it is believed that the adhesive absorbs the stress applied to an original plate, mitigating the effect of the adhesive layer on the flatness of the original plate. A lower limit of the content of the crosslinking agent is preferably 2.000 parts by mass or less, more preferably 1.000 parts by mass or less.

Meanwhile, when the lower limit of the content of the crosslinking agent is 0.002 parts by mass or more, since the crosslinking density is prevented from being excessively low; it is believed that the ease of handling during the production process is maintained, and the generation of adhesive residue is unlikely to occur at the time of peeling the pellicle from an original plate.

As long as the content of the crosslinking agent is in a range of from 0.002 parts by mass to 3.000 parts by mass, a pellicle satisfying Equation (2) can be obtained.

### (1.1.4.4.6) Catalyst

The coating composition may further contain a catalyst. By this, curing of the alkyl (meth)acrylate copolymer can be further accelerated.

The catalyst is, for example, an amine-based catalyst. Examples of the amine-based catalyst include an octylic acid salt of (1,8-diazabicyclo-(5.4.0) undecene-7), and triethylenediamine. The amine-based catalyst may be a product manufactured by San-Apro Ltd., such as “DBU”, “DBN”, “U-CAT”, “U-CAT SAI”, or “U-CAT SA102”.

A content of the catalyst is preferably from 0.002 parts by mass to 3.000 parts by mass, more preferably from 0.10 parts by mass to 1.00 parts by mass, with respect to 100 parts by mass of the alkyl (meth)acrylate copolymer.

### (1.1.4.4.7) Surface Modifier

The coating composition preferably contains no surface modifier. By this, the amount of generated outgas can be reduced.

### (1.1.4.4.8) Additives

If necessary, the coating composition may contain additives, such as a filler, a pigment, a diluent, an age inhibitor, and a tackifier. These additives may be used singly, or in combination of two or more kinds thereof.

### (1.1.4.4.9) Dilution Solvent

The coating composition may also contain a dilution solvent. By this, the viscosity of the coating composition can be adjusted. This consequently makes it easy to control the thickness and the width of the coating composition at the time of applying the coating composition to the other end surface of the pellicle frame.

Examples of the dilution solvent include propyl acetate, acetone, ethyl acetate, and toluene.

The viscosity of the coating composition is preferably 50 Pa·s or less, more preferably from 10 Pa·s to 40 Pa·s, still more preferably from 20 Pa·s to 30 Pa·s.

The viscosity of the coating composition is the viscosity determined when the temperature of the coating composition is 25° C., and can be measured using an E-type viscometer.

(1.1.4.5) Properties, etc. of Adhesive Layer

From the standpoint of, for example, inhibiting the deterioration of the adhesive layer and reducing the amount of outgas, the adhesive layer is preferably insoluble in water. The deterioration of the adhesive layer includes deterioration of the adhesive strength, mask distortion, and the like that are caused by exposure to the moisture and the like in the atmosphere. When the moisture in the air atmosphere adsorbs to the adhesive layer, the generation of outgas caused by the moisture adsorbed to the adhesive layer is likely to occur in a vacuum environment of EUV exposure or the like. The water-insolubility of the adhesive layer indicates that the moisture in the air atmosphere hardly adsorbs to the adhesive layer. Therefore, the adhesive layer that is insoluble in water can reduce the amount of outgas. From the same standpoint, it is preferred that the raw materials of the adhesive layer include the copolymer, and that the copolymer is insoluble in water.

Whether or not the adhesive layer is insoluble in water may be evaluated based on a first gel fraction. The first gel fraction represents a ratio (% by mass) of the mass of the adhesive layer after a first treatment with respect to the mass of the adhesive layer prior to the first treatment. The first treatment refers to a treatment in which the adhesive layer is immersed in water and then stirred with heating at 60° C. for 3 hours to obtain a residue of the adhesive layer not dissolving in water, followed by drying of the thus obtained residue at 100° C. for 3 hours. In the first treatment, the amount of water to be used is 100 parts by mass with respect to 1 part by mass of the adhesive layer. The mass of the adhesive layer after the first treatment represents the mass of the residue of the adhesive layer after the drying. The adhesive layer to be evaluated may be a test piece collected from the adhesive layer.

When the first gel fraction is 70% by mass or less, the adhesive layer may be judged to be soluble in water. When the first gel fraction is 80% by mass or less, the adhesive layer may be judged to be soluble in water. When the first gel fraction is 90% by mass or less, the adhesive layer may be judged to be soluble in water.

Whether or not the copolymer is insoluble in water may be evaluated based on a second gel fraction. The second gel fraction represents a ratio (% by mass) of the mass of the copolymer after a second treatment with respect to the mass of the copolymer prior to the second treatment. The second treatment refers to a treatment in which the copolymer is immersed in water and then stirred with heating at 60° C. for 3 hours to obtain a residue of the copolymer not dissolving in water, followed by drying of the thus obtained residue at 100° C. for 3 hours. In the second treatment, the amount of water to be used is 100 parts by mass with respect to 1 part by mass of the copolymer. The mass of the copolymer after the second treatment represents the mass of the residue of the copolymer after the drying. The copolymer to be evaluated may be a test piece collected from the copolymer.

When the second gel fraction is 70% by mass or less, the copolymer may be judged to be soluble in water. When the second gel fraction is 80% by mass or less, the copolymer may be judged to be soluble in water. When the second gel fraction is 90% by mass or less, the copolymer may be judged to be soluble in water.

From the standpoint of, for example, inhibiting the deterioration of the adhesive layer and reducing the amount of outgas, the adhesive layer may contain a metal ion and an ammonium ion. Examples of the metal ion include a sodium ion, a potassium ion, and a calcium ion.

A total content ratio of the metal ion and the ammonium ion is preferably 4% by mass or less, more preferably 3% by mass or less, still more preferably 2% by mass or less, particularly preferably 1% by mass or less, further preferably 0.5% by mass or less, with respect to a total amount of the adhesive layer.

The total content ratio of the metal ion and the ammonium ion is preferably 4% by mass or less, more preferably 3% by mass or less, still more preferably 2% by mass or less, particularly preferably 1% by mass or less, further preferably 0.5% by mass or less, with respect to a total amount of the monomers configuring the copolymer.

Further, in order to inhibit the contamination of an apparatus with a component derived from an ion such as the metal ion, the total content ratio of the metal ion and the ammonium ion is preferably 4% by mass or less, more preferably 3% by mass or less, still more preferably 2% by mass or less, particularly preferably 1% by mass or less, further preferably 0.5% by mass or less, with respect to the mass of the adhesive layer.

In order to inhibit the contamination of an apparatus with a component derived from an ion such as the metal ion, the total content ratio of the metal ion and the ammonium ion is preferably 4% by mass or less, more preferably 3% by mass or less, still more preferably 2% by mass or less, particularly preferably 1% by mass or less, further preferably 0.5% by mass or less, with respect to a total amount of the monomers configuring the copolymer.

### (1.1.4.6) Thickness

The thickness of the adhesive layer is not particularly limited, and it is preferably from 0.01 mm to 1 mm, more preferably from 0.1 mm to 0.8 mm. When the thickness of the adhesive layer is in this range, distortion of an original plate after pasting can be reduced while ensuring the adhesiveness to the original plate, so that errors in exposure can be eliminated.

### (1.1.5) Pellicle Frame

The pellicle according to one embodiment includes a pellicle frame.

The pellicle frame supports a pellicle film.

The pellicle frame is a cylindrical body. The pellicle frame has a through-hole. This through-hole refers to a space which an exposure light transmitting through the pellicle film passes through to reach an original plate.

The pellicle frame may also have a vent hole. When the pellicle frame is pasted to the original plate, the vent hole connects an inner space of the pellicle and an outer space of the pellicle in communication with each other. The “inner space of the pellicle” refers to a space surrounded by the pellicle and the original plate. The “outer space of the pellicle” refers to a space that is not surrounded by the pellicle and the original plate.

When viewed from the thickness direction, the rectangular pellicle frame consists of four sides.

The length of a longitudinal side is preferably 200 mm or less. The size and the like of the pellicle frame are standardized based on the type of an exposure device. The pellicle frame having a length of 200 mm or less on a longitudinal side satisfies a size standardized for exposure with EUV light.

The length of a transverse side may be, for example, from 5 mm to 180 mm, and it is preferably from 80 mm to 170 mm, more preferably from 100 mm to 160 mm.

The height of the pellicle frame (i.e., the length of the pellicle frame in the thickness direction) is not particularly limited, and it is preferably 3.0 mm or less, more preferably 2.4 mm or less, still more preferably 2.375 mm or less. By this, the pellicle frame satisfies a size standardized for EUV exposure. The height of the pellicle frame standardized for EUV exposure is, for example, 2.375 mm.

The mass of the pellicle frame is not particularly limited, and it is preferably 20 g or less, more preferably 15 g or less. This makes the pellicle frame suitable for the use in EUV exposure.

Examples of a material of the pellicle frame include aluminum, titanium, stainless steel, ceramic materials (e.g., silicon and glass), and resins such as polyethylene.

The shape of the pellicle frame corresponds to the shape of an original plate. Examples of the shape of the pellicle frame include a rectangular frame shape and a square frame shape.

### (1.1.6) Pellicle Film

The pellicle according to one embodiment includes a pellicle film.

The pellicle film not only inhibits the adhesion of foreign matters to the surface of an original plate but also allows an exposure light to pass therethrough during exposure. The foreign matters include dust. Examples of the exposure light include deep ultraviolet (DUV) light and EUV. EUV refers to a light having a wavelength of from 5 nm to 30 nm.

The pellicle film covers the entirety of an opening of the through-hole of the pellicle frame on one end-surface side. The pellicle film may be supported at one end surface of the pellicle frame either directly or via an adhesive agent layer (hereinafter, also referred to as “film adhesive agent layer”). This film adhesive agent layer may be a cured product of any known adhesive agent.

The pellicle film preferably has a thickness of from 1 nm to 200 nm. A material of the pellicle film is not particularly limited, and examples thereof include carbon-based materials, SiN, and polysilicon. Examples of the carbon-based materials include carbon nanotubes (hereinafter, also referred to as “CNTs”). Thereamong, the material of the pellicle film 12 preferably contains CNTs. The CNTs may be single-wall CNTs or multi-wall CNTs, or may contain a combination of single-wall CNTs and multi-wall CNTs.

The pellicle film may have a nonwoven fabric structure. The nonwoven fabric structure is formed by, for example, fiber-shaped CNTs.

### (1.1.7) Protective Film

The pellicle according to one embodiment may include a protective film (liner) if necessary.

The protective film protects at least an original plate-contacting surface of the adhesive layer. The protective film is peelable from the adhesive layer.

The protective film has a thickness of preferably from 5 μm to 500 μm, more preferably from 30 μm to 200 μm. Examples of a material of the protective film include polyester.

A mold release agent may be applied to a surface of the protective film at a side coming into contact with the adhesive layer. Examples of the mold release agent include silicone-based mold release agents and fluorine-containing mold release agents.

### (1.1.8) Exposure Original Plate

The exposure original plate according to one embodiment includes an original plate and the pellicle according to one embodiment. The original plate has a pattern. The pellicle according to one embodiment is pasted to a surface of the original plate at the side having the pattern.

The exposure original plate according to one embodiment includes the pellicle according to one embodiment: therefore, even when it is exposed to a high-temperature environment (e.g., 60° C.), the pellicle is unlikely to be peeled off from the original plate.

In the original plate, for example, a support substrate, a reflective layer, and an absorbent layer may be disposed in layers in the order mentioned. The absorbent layer absorbs a portion of light (e.g., EUV), as a result of which a desired image is formed on a sensitive substrate (e.g., a semiconductor substrate equipped with a photoresist film). The reflective layer may be, for example, a multilayer film of molybdenum (Mo) and silicon (Si). A material of the absorbent layer may be a material having a high absorbance for EUV or the like. Examples of the material having a high absorbance for EUV or the like include chromium (Cr) and tantalum nitride.

### (1.1.9) Exposure Device

The exposure device according to one embodiment includes: a light source: the exposure original plate according to one embodiment: and an optical system. The light source emits an exposure light. The optical system guides the exposure light emitted from the light source to the exposure original plate. The exposure original plate is arranged such that the exposure light emitted from the light source transmits through the pellicle film and is irradiated onto the original plate.

The exposure device not only is capable of forming a pattern refined by EUV or the like (e.g., a pattern having a line width of 32 nm or less), but also can perform pattern exposure in which defects in resolution caused by foreign matters are reduced even in the case of using EUV where defects in resolution caused by foreign matters tend to be a problem.

The exposure light is preferably EUV. EUV has a short wavelength and is thus readily absorbed by a gas such as oxygen or nitrogen. Therefore, exposure with EUV light is performed in a vacuum environment.

### (1.2) Method of Producing Pellicle

The method of producing a pellicle according to one embodiment of the disclosure is a method of producing the pellicle according to one embodiment, and includes the below-described pellicle film attaching step and the below-described adhesive layer forming step. By this method, a pellicle satisfying Equation (1) is obtained.

The order of performing the pellicle film attaching step and the adhesive layer forming step is not particularly limited.

### (1.2.1) Pellicle Film Attaching Step

In the pellicle film attaching step, the pellicle film is attached to one end surface of the pellicle frame.

A method of attaching the pellicle film to one end surface of the pellicle frame is not particularly limited, and one example thereof is a method of applying a known adhesive agent to one end surface of the pellicle frame to form a film adhesive agent layer and subsequently arranging the pellicle film on this film adhesive agent layer.

### (1.2.2) Adhesive Layer Forming Step

In the adhesive layer forming step, the above-described coating composition is applied to the other end surface of the pellicle frame and then heated to form an adhesive layer. As a result, the coating composition is dried and cured, whereby an adhesive composition (adhesive layer) is obtained.

### (1.2.2.1) Application Method

A method of applying the coating composition to the other end surface of the pellicle frame is not particularly limited and, for example, a method using a dispenser may be employed.

The thickness of the coating composition is preferably from 0.1 mm to 4.5 mm, more preferably from 0.1 mm to 3.5 mm, still more preferably from 0.2 mm to 2 mm.

### (1.2.2.2) Heat-Drying

A method of heating the coating composition is not particularly limited, and any known method may be employed.

The temperature of heating the coating composition is selected as appropriate in accordance with, for example, the boiling points of a solvent and a residual monomer, and the decomposition temperature and the like of the alkyl (meth) acrylate copolymer, and it is preferably from 50°° C. to 200°° C., more preferably from 60° C. to 190° C.

By heating the coating composition, volatile compounds such as a solvent and a residual monomer are removed from the resulting adhesive layer.

When the coating composition contains a crosslinking agent, the functional group of the alkyl (meth)acrylate copolymer and the crosslinking agent are reacted with each other by the heating to form a crosslinked structure in the adhesive layer, yielding a reaction product of the alkyl (meth)acrylate copolymer and the crosslinking agent. By this heat-drying, the adhesive layer tightly adheres to the pellicle frame surface, as a result of which the pellicle frame and the adhesive layer are integrated.

### (2) MODIFICATION EXAMPLE

### (2.1) Pellicle

The pellicle according to a modification example of the disclosure includes: a pellicle frame: a pellicle film supported at one end surface of the pellicle frame: and an adhesive layer provided at another end surface of the pellicle frame, and the adhesive layer may have a glass transition temperature Tg of higher than −25° C. and lower than 10° C.

The glass transition temperature Tg of the adhesive layer is measured by the same method as described below in the section of Examples.

In this modification example, the pellicle has the above-described constitution, and is thus unlikely to be peeled off from an original plate even when exposed to a high-temperature environment (e.g., 60° C.).

The pellicle according to the modification example is the same as the pellicle according to one embodiment, except that the adhesive layer has a glass transition temperature Tg of higher than −25° C. and lower than 10° C., and that the pellicle according to the modification example does not have to satisfy the above-described Equation (1). For the description of the modification example of the disclosure, the above description of one embodiment of the disclosure can be incorporated.

A preferred range and the like of the glass transition temperature Tg of the adhesive layer are the same as in one embodiment.

### (2.1.1) First Peel Strength

In the modification example, the pellicle preferably satisfies the above-described Equation (1). This, as described above, makes the pellicle according to the modification example unlikely to be peeled off from an original plate even when exposed to a high-temperature environment (e.g., 60° C.).

A preferred range and the like of the first peel strength are the same as in one embodiment.

### (2.1.2) Peel Strength Ratio

The pellicle according to the modification example preferably satisfies the above-described Equation (2). By this, as described above, the generation of adhesive residue can be inhibited.

A preferred range of the peel strength ratio ([A_{60° C.}]/[A_{23° C.}]), a method for satisfying Equation (2), and the like are the same as in one embodiment.

### (2.1.3) Second Peel Strength

A preferred range of the second peel strength is the same as in one embodiment.

### (2.1.4) Adhesive Layer

The pellicle according to the modification example includes an adhesive layer. The adhesive layer enables to adhere the pellicle according to the modification example to an original plate.

The adhesive layer is a gel-like viscoelastic body in the same manner as in one embodiment. As described below; the adhesive layer is formed by processing a coating composition through coating, heating, drying, curing, and the like.

### (2.1.4.1) Coating Composition

The coating composition is a precursor of an adhesive composition, which contains a composition containing a compound selected from various polymers, solvents, crosslinking agents, catalysts, initiators, and the like in accordance with the adhesive layer to be formed. In other words, an adhesive composition is obtained by curing the coating composition.

### (2.1.4.2) Adhesive Composition

Examples of the adhesive composition include, but not particularly limited to, acrylic, silicone-based, styrene butadiene-based, urethane-based, and olefin-based adhesives. Thereamong, from the standpoint of, for example, reducing the amount of outgas generated from the pellicle, the adhesive composition is preferably an acrylic adhesive.

The acrylic adhesive will now be described. The acrylic adhesive and the like according to the modification example are the same as in one embodiment.

### (2.1.4.3) Acrylic Adhesive

The acrylic adhesive preferably contains an alkyl (meth)acrylate copolymer.

The alkyl (meth)acrylate copolymer preferably contains a copolymer of:
an alkyl (meth)acrylate monomer: and
a monomer having a functional group that is reactive with at least one of an isocyanate group, an epoxy group, or an acid anhydride.

The acrylic adhesive contains the alkyl (meth) acrylate copolymer: therefore, the pellicle has a sufficient first peel strength, and the generation of adhesive residue can be inhibited.

The alkyl (meth)acrylate monomer preferably contains at least one of an alkyl group having from 1 to 3 carbon atoms or an alicyclic alkyl group.

By this, a sufficient first peel strength is likely to be obtained.

It is preferred that:
the alkyl (meth) acrylate copolymer contains a copolymer of an alkyl (meth) acrylate monomer and a monomer having a functional group that is reactive with at least one of an isocyanate group, an epoxy group, or an acid anhydride; and
the alkyl (meth) acrylate monomer contains at least one of an alkyl group having from 1 to 3 carbon atoms or an alicyclic alkyl group.

By this, not only the pellicle has a sufficient first peel strength and can inhibit the generation of adhesive residue, but also the amount of generated outgas can be further reduced.

The content of the alkyl (meth) acrylate monomer is preferably from 80 parts by mass to 99.5 parts by mass with respect to a total of 100 parts by mass of the monomers configuring the copolymer.

When the content of the alkyl (meth) acrylate monomer is in a range of from 80 parts by mass to 99.5 parts by mass, an appropriate adhesive strength can be realized.

The content of the functional group-containing monomer is preferably, for example, from 0.5 parts by mass to 20 parts by mass with respect to a total of 100 parts by mass of the monomers configuring the copolymer.

### (2.1.5) Pellicle Frame and Pellicle Film

In the modification example, the pellicle frame, the pellicle film, and the like are the same as in one embodiment.

### (2.1.6) Protective Film

The pellicle according to the modification example may include a protective film (liner) if necessary. The protective film and the like are the same as in one embodiment.

### (2.1.7) Exposure Original Plate

The exposure original plate according to the modification example includes an original plate and the pellicle according to the modification example. The original plate has a pattern. The pellicle according to the modification example is pasted to a surface of the original plate at the side having the pattern.

The exposure original plate according to the modification example includes the pellicle according to the modification example: therefore, even when it is exposed to a high-temperature environment (e.g., 60° C.), the pellicle is unlikely to be peeled off from the original plate.

The original plate and the like are the same as in one embodiment.

### (2.1.8) Exposure Device

The exposure device according to the modification example includes: a light source: the exposure original plate according to the modification example: and an optical system. The light source emits an exposure light. The optical system guides the exposure light emitted from the light source to the exposure original plate. The exposure original plate is arranged such that the exposure light emitted from the light source transmits through the pellicle film and is irradiated onto the original plate.

The functions, the exposure light, and the like of the exposure device are the same as in one embodiment.

### (2.2) Method of Producing Pellicle

The method of producing a pellicle according to the modification example of the disclosure is a method of producing the pellicle according to the modification example, and includes the pellicle film attaching step and the adhesive layer forming step. By this method, a pellicle that includes an adhesive layer having a glass transition temperature Tg in a range of higher than −25° C. and lower than 10° C. is obtained.

The order of performing the pellicle film attaching step and the adhesive layer forming step is not particularly limited.

The pellicle film attaching step, the adhesive layer forming step, and the like are the same as in one embodiment.

### EXAMPLES

The disclosure will now be described in more detail by way of Examples: however, the inventions of the disclosure are not limited only to the below-described Examples.

The components used in Examples and Comparative Examples are as follows.

### <Alkyl (Meth) Acrylate Monomers>

EA: ethyl acrylate (Tg: −24° C.)
MMA: methyl methacrylate
BA: butyl acrylate

### <Functional Group-Containing Monomers>

4-HBA: 4-hydroxybutyl acrylate
HEMA: 2-hydroxyethyl methacrylate
GMA: glycidyl methacrylate

### <Crosslinking Agents>

“RIKACID MH-700G”, manufactured by New Japan Chemical Co., Ltd.
AIBN: 2,2′-azobisisobutyronitrile (10-hour half-life temperature: 65°° C.)
Peroxide-based radical generator: “PERKADOX 12-XL25” (active ingredient concentration: 25%), manufactured by Kayaku Akzo Co., Ltd.
Photoradical generator: “OMNIRAD 1173”, manufactured by IGM Resins B.V.

### <Polymerization Solvent>

propyl acetate

### <Catalyst>

Amine-based catalyst: “U-CAT SA-102” (chemical formula: (1,8-diazabicyclo-(5.4.0)undecene-7) octylate), manufactured by San-Apro Ltd.

### Example 1

An alkyl (meth) acrylate copolymer was prepared by a well-known method.

Specifically, a reaction vessel equipped with a stirrer, a thermometer, a reflux condenser, a dripping device, and a nitrogen introduction tube was prepared. To this reaction vessel, a polymerization solvent (180 parts by mass) was added, and a mixture (423.4 parts by mass) of EA/4-HBA/HEMA/GMA/AIBN (crosslinking agent) was further added at a mass ratio of 378/12.6/21/8.4/3.4. In a nitrogen atmosphere, this reaction solution was allowed to react at 85° C. for 6 hours and then at 95° C. for 2 hours, whereby an acrylic copolymer solution having a nonvolatile component (copolymer) concentration of 70% by mass (weight-average molecular weight: 119,000) was obtained.

To the thus obtained acrylic copolymer solution (143 parts by mass), a crosslinking agent (“MH-700G”) (0.28 parts by mass) and a catalyst (“U-CAT SA-102”) (0.93 parts by mass) were added, and the resultant was mixed with stirring to obtain a coating composition.

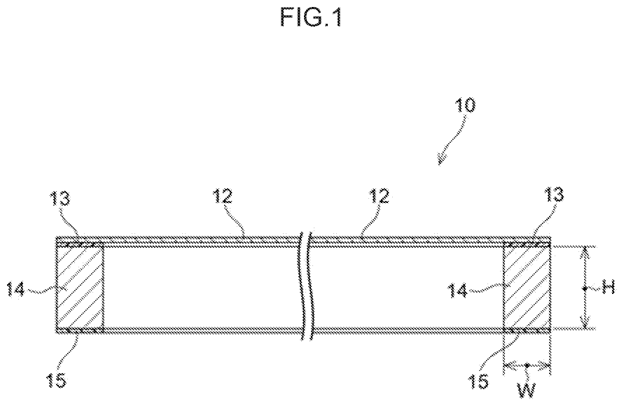

As illustrated in FIG. 1, an anodized aluminum pellicle frame (external dimensions: 149 mm×115 mm, frame height H: 4.5 mm, frame width W: 2 mm) was prepared as a pellicle frame 14. The above-prepared coating composition was applied to one end surface of the pellicle frame 14 using a dispenser. This was dried at 100° C. for 120 minutes, and a protective film was arranged on the thus dried coating composition and then dried at 120° C. for 20 hours to form an adhesive layer 15 (thickness: 0.2 mm) made of an adhesive composition. On the other end surface of the pellicle frame 14 (on the end surface of the side without the formation of the adhesive layer 15), a pellicle film 12 was pasted via a film adhesive agent layer 13. In this manner, a pellicle 10 was obtained.

The thus obtained pellicle 10 was evaluated by the below-described methods.

### [Measurement of First Peel Strength]

(1) A cleaned quartz glass substrate (model “#6025 substrate” manufactured by HOYA Corporation, size: 152 mm×152 mm×6.35 mm) was prepared.

(2) The protective film was removed from the adhesive layer 15 and, using a pellicle mounter manufactured by Matsushita Seiki Co., Ltd., the pellicle 10 was pasted onto the quartz glass substrate with application of a load of 5 kgf for 30 seconds such that the adhesive layer 15 was brought into contact with a surface of the quartz glass substrate, whereby a laminated body was obtained.

(3) The thus obtained laminated body was stored (left to stand) at 23° C. for 24 hours to stabilize the adhesion strength. In this manner, a test laminated body was obtained.

The test laminated body consisted of the quartz glass substrate and the pellicle 10. The pellicle 10 was adhered to the quartz glass substrate via the adhesive layer 15.

Two long sides of the pellicle frame 14 of the test laminated body were held using a universal material tester (“RTG-1310”, manufactured by A&D Co., Ltd.) and a jig, and a load cell for load measurement in the standard universal tester was set at a rate of 0.1 mm/sec. Under a condition that the temperature of the quartz glass substrate was 60° C., the pellicle 10 was pulled vertically upward (in the height direction of the pellicle frame 14) and, in this process, the “first peel strength (gf/mm²)” was calculated from a maximum load applied before the adhesive layer 15 was peeled off from the quartz glass substrate.

An acceptable first peel strength is 4.0 gf/mm² or more. The measurement result is shown in Table 1.

### [Measurement of Second Peel Strength]

A maximum load applied before the adhesive layer 15 was peeled off from the quartz. glass substrate was measured in the same manner as in the measurement of the first peel strength, except that the measurement was performed in a 23° C. air atmosphere under a condition tha the temperature of the quartz glass substrate was 23° C. The “second peel strength (gf/mm²)” was calculated from the thus measured load.

An acceptable second peel strength is 4.0 gf/mm² or more. The measurement result is shown in Table 1.

### [Adhesive Residue Evaluation Test]

Adhesive residues on each of the quartz glass substrate after the measurement of the first peel strength and the quartz glass substrate after the measurement of the second peel strength were evaluated based on the below-described criteria.

An acceptable evaluation is “A” or “B”. The measurement results are shown in Table 1.

In the following criteria, the “area of adhesive residue” represents the area of the adhesive layer 15 that remained on the quartz glass substrate after peeling the pellicle 10.

The “adhesion area” represents the area of a portion of the surface of the quartz glass substrate that came into contact with the adhesive layer 15.

A: The ratio of the area of adhesive residue with respect to the adhesion area was 0% by area or higher and lower than 10% by area.

B: The ratio of the area of adhesive residue with respect to the adhesion area was 10% by area or higher and lower than 30% by area.

C: The ratio of the area of adhesive residue with respect to the adhesion area was 30% by area or higher.

The measurement result is shown in Table 1.

### [Glass Transition Temperature (Tg)]

The glass transition temperature (Tg) of the adhesive composition (adhesive layer) prior to the pasting of the pellicle 10 onto the quartz glass substrate was measured in accordance with JIS K7112. Specifically, the glass transition temperature (Tg) of the adhesive composition prior to the pasting of the pellicle 10 onto the quartz glass substrate was measured using a differential scanning calorimeter (DSC) at a heating rate of 20° C./min in a nitrogen atmosphere.

The measurement result is shown in Table 1.

### [Viscosity]

The viscosity of the copolymer solution was measured by the above-described method.

The measurement result is shown in Table 1.

[Measurement of Weight-Average Molecular Weight (Mw) and Number-Average Molecular Weight (Mn) of Alkyl (meth) acrylate Copolymer]

The GPC conditions used for measuring the weight-average molecular weight (Mw) and the number-average molecular weight (Mn) of the alkyl (meth) acrylate copolymer are as follows.

### <GPC Conditions>

Pump: “LC-10AD”, manufactured by Shimadzu Corporation
Oven: “CT020A”, manufactured by Shimadzu Corporation
Detector: “RI-101”, manufactured by Showa Denko K.K.
Data processing software: “EMPOWER 3”, manufactured by Waters Corporation
GPC columns: “PLgel MIXED-B” (7.5×300 mm)×2, manufactured by Agilent Technologies, Inc.
Column temperature: 40° C.
Elution solvent: tetrahydrofuran
Flow rate: 1.0 mL/min
Sample concentration: 0.1% (w/v)
Sample injection amount: 100 μL
Standard substance: monodisperse polystyrene

### Example 2

An acrylic copolymer solution having a nonvolatile component concentration of 70% by mass (weight-average molecular weight: 138,000) was obtained by performing a reaction under the same conditions as in Example 1, except that EA, 4-HBA, and GMA were added at the respective mass ratios shown in Table 1. The thus obtained solution was applied and processed, and various evaluations of the thus obtained pellicle 10 were performed in the same manner as in Example 1.

### Example 3

An acrylic copolymer solution having a nonvolatile component concentration of 70% by mass (weight-average molecular weight: 105,000) was obtained by performing a reaction under the same conditions as in Example 1, except that EA, MMA, 4-HBA, HEMA, and GMA were added at the respective mass ratios shown in Table 1. The thus obtained solution was applied and processed, and various evaluations of the thus obtained pellicle 10 were performed in the same manner as in Example 1.

It is noted here that, in Example 3, the value of the second peel strength was higher than 26.0 gf/mm² due to breakage of the quartz glass substrate during the measurement of the second peel strength.

### Example 4

An acrylic copolymer solution having a nonvolatile component concentration of 70% by mass (weight-average molecular weight: 136,000) was obtained by performing a reaction under the same conditions as in Example 1, except that EA, BA, 4-HBA, and GMA were added at the respective mass ratios shown in Table 1. The thus obtained solution was applied and processed, and various evaluations of the thus obtained pellicle 10 were performed in the same manner as in Example 1.

### Example 5

An acrylic copolymer solution having a nonvolatile component concentration of 70% by mass (weight-average molecular weight: 134,000) was obtained by performing a reaction under the same conditions as in Example 1, except that the added amount of the crosslinking agent (“RIKACID MH-700G”) was changed as shown in Table 1. The thus obtained solution was applied and processed, and various evaluations of the thus obtained pellicle 10 were performed in the same manner as in Example 1.

### Comparative Example 1

A resin composition was obtained by adding 4 parts by mass of a peroxide-based radical generator (“PERKADOX 12-XL25”) and 0.01 parts by mass of a photoradical generator (“OMNIRAD 1173”) to 100 parts by mass of a reactive acrylic polymer “ART CURE RA-341” (solid concentration: 100%) manufactured by Negami Chemical Industrial Co., Ltd.

The thus obtained resin composition was applied to one end surface of the pellicle frame 14 using a dispenser to obtain a coated product. The thus obtained coated product was dried at 60° C. for 30 minutes and then photo-cured by irradiation with 410 mJ/cm² ultraviolet (UV) rays. A protective film was arranged on this coated product, and this was followed by drying at 120° C. for 20 hours to form an adhesive layer 15 (thickness: 0.2 mm) made of an adhesive composition. On the other end surface (the end surface of the side without the formation of the pellicle layer 15) of the pellicle frame 14 having the adhesive layer 15 (thickness: 0.2 mm) formed thereon, a pellicle film 12 was pasted via a film adhesive agent layer 13. In this manner, a pellicle 10 was obtained.

Various evaluations of the thus obtained pellicle 10 were performed in the same manner as in Examples 1 to 3.

### Comparative Example 2

An acrylic copolymer solution having a nonvolatile component concentration of 70% by mass (weight-average molecular weight: 186,000) was obtained by performing a reaction under the same conditions as in Example 1, except that BA, HEMA, and GMA were added at the respective mass ratios shown in Table 1. The thus obtained solution was applied and processed and various evaluations of the thus obtained pellicle 10 were performed in the same manner as in Example 1.

TABLE 1

| | Coating composition | | | | | | | | | | | | | |
|---|---|---|---|---|---|---|---|---|---|---|---|---|---|---|
| | Copolymer | | | | | | | | | Copo- | Additive | | | |
| | Alkyl (meth)acrylate | | | Functional group- | | | GPC measurement | | | lymer | | | | Cata- |
| | monomer | | | containing monomer | | | results | | | solution | Crosslinking agent | | | lyst |
| | EA | MMA | BA | 4-HBA | HEMA | GMA | | | Mw/ | Viscosity | 12XL25 | 1173 | MH700G | SA102 |
| | parts | parts | parts | parts | parts | parts | Mw | Mn | Mn | Pa · s | parts | parts | parts | parts |
| Com- | — | — | — | — | — | — | — | — | — | — | 4 | 0.01 | 0 | 0 |
| parative | | | | | | | | | | | | | | |
| Example 1 | | | | | | | | | | | | | | |
| Example 1 | 90 | 0 | 0 | 3 | 5 | 2 | 119,000 | 30,600 | 3.9 | 57 | 0 | 0 | 0.28 | 0.93 |
| Example 2 | 90 | 0 | 0 | 8 | 0 | 2 | 138,000 | 29,900 | 4.6 | 91 | 0 | 0 | 0.28 | 0.93 |
| Example 3 | 77 | 13 | 0 | 3 | 5 | 2 | 105,000 | 31,100 | 3.4 | 158 | 0 | 0 | 0.28 | 0.93 |
| Com- | 0 | 0 | 90 | 0 | 8 | 2 | 186,000 | 36,000 | 5.2 | 30 | 0 | 0 | 0.28 | 0.93 |
| parative | | | | | | | | | | | | | | |
| Example 2 | | | | | | | | | | | | | | |
| Example 4 | 77 | 0 | 13 | 8 | 0 | 2 | 136,000 | 26,100 | 5.2 | 50 | 0 | 0 | 0.28 | 0.93 |
| Example 5 | 90 | 0 | 0 | 3 | 5 | 2 | 134,000 | 41,400 | 3.2 | 57 | 0 | 0 | 0.001 | 0.93 |

TABLE 2

| | Adhesive composition | | | | | |
|---|---|---|---|---|---|---|
| | | Evaluation | | | | |
| | | Substrate | | Substrate | | |
| | | temperature: 60° C. | | temperature: 23° C. | | |
| | | First | | Second | | |
| | | peel | | peel | | |
| | | strength | Ad- | strength | Ad- | |
| | Tg | [A_{60°C}] | hesive | [A_{23°C}] | hesive | [A_{60°C}]/ |
| | ° C. | (gf/mm²) | residue | (gf/mm²) | residue | [A_{23°C}] |
| Com- | −44.3 | 2.3 | A | 6.3 | A | 0.37 |
| parative | | | | | | |
| Example 1 | | | | | | |
| Example 1 | −15.8 | 13.5 | A | 25.7 | A | 0.53 |
| Example 2 | −19.6 | 5.2 | A | 11.5 | A | 0.45 |
| Example 3 | −7.2 | 14.6 | A | >26 | A | — |
| Com- | −43.6 | 3.25 | A | 8.62 | A | 0.38 |
| parative | | | | | | |
| Example 2 | | | | | | |
| Example 4 | −24.2 | 12.90 | A | 26.20 | A | 0.48 |
| Example 5 | −17.6 | 17.70 | A | 45.10 | B | 0.39 |

In Table 2, “Substrate temperature” indicates the temperature of a quartz glass substrate. In Table 1, “Copolymer solution” indicates an acrylic copolymer solution. In Table 1, “parts” of each monomer under “Copolymer” indicates the mass ratio of each monomer with respect to a total of 100 parts by mass of the monomers configuring the respective copolymer. In Table 1, “parts” of each component under “Additive” indicates the mass ratio of each component, taking the mass of solid components of the respective copolymer solution (i.e., a total mass of the monomers configuring each copolymer) as 100 parts. In Table 1, “12XL25” denotes “PERKADOX 12-XL25”, “1173” denotes “OMNIRAD 1173”, “SA102” denotes “U-CAT SA-102”, and “MH700G” denotes “RIKACID MH-700G”.

The pellicle of Comparative Example I included a pellicle frame, a pellicle film, and an adhesive layer. The pellicle of Comparative Example 1 had a [A_{60° C.}] value of 2.3 gf/mm², which is not 4.0 gf/mm² or more. Therefore, it was found that the pellicle of Comparative Example 1 is likely to be peeled off from a photomask when exposed to a high-temperature environment (e.g., 60° C.).

The pellicle of Comparative Example 2 had a [A_{60° C.}] value of 3.25 gf/mm², which is not 4.0 gf/mm² or more. Therefore, it was found that the pellicle of Comparative Example 2 is likely to be peeled off from a photomask when exposed to a high-temperature environment (e.g., 60°° C.).

The pellicles of Examples 1 to 5 had a [A_{60° C.}] value of 4.0 gf/mm² or more. Therefore, it was found that the pellicles of Examples 1 to 5 are unlikely to be peeled off from a photomask even when exposed to a high-temperature environment (e.g., 60° C.).

Further, comparing Examples 1 to 4 with Example 5, the value of [A_{60° C.}]/[A_{23° C.}] was 0.39 and the adhesive residue at 23° C. was evaluated as “B” in Example 5. In Examples 1 to 4, the value of [A_{60° C.}]/[A_{23° C.}] was 0.40 or more and the adhesive residue at 23° C. was evaluated as “A”, which are both superior. As a cause of this, it is believed that the adhesive composition of Examples 1 to 4 contained an appropriate amount of a crosslinking agent (MH700G), which is different from the adhesive composition of Example 5, and, therefore, the crosslinking density was not excessively low and an adhesive residue was hardly generated at the time of peeling the pellicle from an original plate.

The disclosure of Japanese Patent Application No. 2021-148630 filed on Sep. 13, 2021 is hereby incorporated by reference in its entirety.

All the documents, patent applications, and technical standards that are described in the present specification are hereby incorporated by reference to the same extent as if each individual document, patent application, or technical standard is concretely and individually described to be incorporated by reference.

1. A pellicle, comprising:
a pellicle frame;
a pellicle film supported at one end surface of the pellicle frame; and
an adhesive layer provided at another end surface of the pellicle frame,
wherein the pellicle satisfies the following Equation (1):
$$[ {A}_{6 {0}^{∘} C .} ] \geq 4. gf / {mm}^{2} \qquad Equation ( 1 )$$
wherein:
[A_{60° C.}] represents a first peel strength when the pellicle is used in a test laminated body,
the test laminated body is obtained by placing the pellicle on a quartz glass substrate such that the adhesive layer is in contact with a surface of the quartz glass substrate, maintaining a load of 5 kgf on the pellicle for 30 seconds, removing the load, and then leaving the resultant to stand at 23° C. for 24 hours, and
the first peel strength represents a load per unit adhesion area, which load is required for peeling the pellicle included in the test laminated body from the quartz glass substrate at a time of pulling the pellicle frame in a height direction of the pellicle frame at a rate of 0.1 mm/sec with respect to the quartz glass substrate using a standard universal tester under a condition that the temperature of the quartz glass substrate is 60° C.

2. The pellicle according to claim 1, wherein the pellicle satisfies the following Equation (2):
$$( [ {A}_{6 {0}^{∘} C .} ] / [ {A}_{2 {3}^{∘} C .} ] ) \geq 0.40 \qquad Equation ( 2 )$$
wherein:
[A_{23° C.}] represents a second peel strength when the pellicle is used in the test laminated body, and
the second peel strength represents a load per unit adhesion area, which load is required for peeling the pellicle included in the test laminated body from the quartz glass substrate at a time of pulling the pellicle frame in the height direction of the pellicle frame at a rate of 0.1 mm/sec with respect to the quartz glass substrate using a standard universal tester under a condition that the temperature of the quartz glass substrate is 23° C.

3. The pellicle according to claim 1, wherein the pellicle satisfies the following Equation (3):
$$[ {A}_{2 {3}^{∘} C .} ] \leq 30. gf / {mm}^{2} . \qquad Equation ( 3 )$$

4. The pellicle according to claim 1, wherein the adhesive layer has a glass transition temperature Tg of higher than −25° C. and lower than 10° C.

5. The pellicle according to claim 1, wherein the adhesive layer comprises a copolymer of an alkyl (meth) acrylate monomer and a monomer comprising a functional group that is reactive with at least one of an isocyanate group, an epoxy group, or an acid anhydride.

6. The pellicle according to claim 5, wherein the alkyl (meth) acrylate monomer comprises at least one of an alkyl group having from 1 to 3 carbon atoms or an alicyclic alkyl group.

7. The pellicle according to claim 4, wherein:
the adhesive layer comprises a copolymer of an alkyl (meth) acrylate monomer and a monomer comprising a functional group that is reactive with at least one of an isocyanate group, an epoxy group, or an acid anhydride, and
the alkyl (meth) acrylate monomer comprises at least one of an alkyl group having from 1 to 3 carbon atoms or an alicyclic alkyl group.

8. The pellicle according to claim 6, wherein a content of the alkyl (meth) acrylate monomer is from 80 parts by mass to 99.5 parts by mass with respect to a total of 100 parts by mass of the monomers configuring the copolymer.

9. The pellicle according to claim 6, wherein a content of the monomer comprising the functional group is from 0.5 parts by mass to 20 parts by mass with respect to a total of 100 parts by mass of the monomers configuring the copolymer.

10. The pellicle according to claim 6, wherein:
the adhesive layer comprises a reaction product of the copolymer and a crosslinking agent, and
a content of the crosslinking agent is from 0.002 parts by mass to 3.000 parts by mass with respect to a total of 100 parts by mass of the monomers configuring the copolymer.

11. An exposure original plate, comprising:
an original plate having a pattern; and
the pellicle according to claim 1, which is attached to a surface of the original plate at a side having the pattern.

12. An exposure device, comprising:
a light source that emits an exposure light;
the exposure original plate according to claim 11; and
an optical system that guides the exposure light emitted from the light source to the exposure original plate,
wherein the exposure original plate is arranged such that the exposure light emitted from the light source transmits through the pellicle film and is irradiated onto the original plate.

13. A method of producing the pellicle according to claim 1, the method comprising:
attaching the pellicle film to one end surface of the pellicle frame; and
forming the adhesive layer by applying a coating composition to the other end surface of the pellicle frame and heating the applied coating composition,
wherein the coating composition comprises a copolymer of an alkyl (meth) acrylate monomer and a monomer comprising a functional group that is reactive with at least one of an isocyanate group, an epoxy group, or an acid anhydride.
